(19) United States
(12) Patent Application Publication
(10) Pub. No.: US 2026/0096284 A1
(43) Pub. Date: Apr. 2, 2026

(54) ELECTRO-OPTICAL DEVICE AND ELECTRONIC INSTRUMENT

(71) Applicant: SEIKO EPSON CORPORATION, Tokyo (JP)

(72) Inventor: Yuiga HAMADE, MATSUMOTO-SHI (JP)

(73) Assignee: SEIKO EPSON CORPORATION, Tokyo (JP)

(21) Appl. No.: 19/337,929

(22) Filed: Sep. 24, 2025

(30) Foreign Application Priority Data
Sep. 27, 2024 (JP) 2024-168612

(51) Int. Cl. H10K 50/19; G02B 27/01; H10K 50/13; H10K 50/818; H10K 50/828

(52) U.S. Cl. CPC H10K 50/19; G02B 27/0172; H10K 50/13; H10K 50/818; H10K 50/828; G02B 2027/0178

(57) ABSTRACT

An electro-optical device includes: a light emitting element including a first electrode having reflectivity, a first light emitting layer configured to emit light in a first wavelength region including a first wavelength, a donor layer, an acceptor layer in contact with the donor layer, a second light emitting layer configured to emit light in a second wavelength region including a second wavelength, and a second electrode having reflectivity and transparency, stacked in order. The first wavelength region and the second wavelength region overlap partially or entirely.

The present application is based on, and claims priority from JP Application Ser. No. 2024-168612, filed Sep. 27, 2024, the disclosure of which is hereby incorporated by reference herein in its entirety.

### BACKGROUND

### 1. Technical Field

The present disclosure relates to an electro-optical device and an electronic instrument.

### 2. Related Art

There has been known an electro-optical device using, for example, an organic light emitting diode (OLED) as a light emitting element. In such an electro-optical device using an OLED, there has been known a technique of using a so-called tandem element in which two or more light emitting units are coupled in series in order to secure high luminance (for example, refer to JP-A-2006-302506). In such a tandem element, twice the luminance can be achieved at the same current amount as compared with a structure with one light emitting unit.

JP-A-2006-302506 is an example of the related art.

However, in the tandem element as described in JP-A-2006-302506, a drive voltage required may be more than twice as high. In particular, in a micro display in which a pixel pitch is about several μm and a drive circuit or a pixel portion is formed on a semiconductor substrate, since a size of a transistor which is a constituent element is restricted, a drive voltage cannot be increased.

### SUMMARY

An electro-optical device according to one aspect of the present disclosure includes: a light emitting element including a first electrode having reflectivity, a first light emitting layer configured to emit light in a first wavelength region including a first wavelength, a donor layer, an acceptor layer in contact with the donor layer, a second light emitting layer configured to emit light in a second wavelength region including a second wavelength, and a second electrode having reflectivity and transparency, stacked in order. The first wavelength region and the second wavelength region overlap partially or entirely.

### BRIEF DESCRIPTION OF THE DRAWINGS

FIG. 1 is a diagram illustrating a configuration of an electro-optical device according to a first embodiment.

FIG. 2 is a block diagram illustrating an electric configuration of the electro-optical device.

FIG. 3 is a circuit diagram illustrating a pixel portion in the electro-optical device.

FIG. 4 is a timing chart illustrating an operation of the electro-optical device.

FIG. 5 is a plan view illustrating the pixel portion in the electro-optical device.

FIG. 6 is a diagram illustrating organic layers and the like stacked on a pixel electrode in the electro-optical device.

FIG. 7 is a diagram illustrating an example of thicknesses of the organic layers and the like in the electro-optical device.

FIG. 8 is a diagram illustrating organic layers and the like stacked on a pixel electrode in a comparative example.

FIG. 9 is a diagram illustrating an example of thicknesses of the organic layers and the like in the comparative example.

FIG. 10 is a diagram illustrating drive voltage-current density characteristics in the first embodiment and the comparative example.

FIG. 11 is a diagram illustrating emission spectra in the first embodiment and the comparative example.

FIG. 12 is a diagram illustrating luminance and chromaticity in the first embodiment and the comparative example.

FIG. 13 is a diagram illustrating a light emitting position in the comparative example.

FIG. 14 is a diagram illustrating a light emitting position in the first embodiment.

FIG. 15 is a perspective view illustrating a head-mounted display using the electro-optical device according to the embodiment and the like.

FIG. 16 is a diagram illustrating an optical configuration of the head-mounted display.

### DESCRIPTION OF EMBODIMENTS

Hereinafter, an electro-optical device according to an embodiment of the present disclosure will be described with reference to the drawings. Note that, in the drawings, dimensions and scales of the respective parts are appropriately made different from real ones. Further, the following embodiment is a preferable specific example of the present disclosure and therefore various technically preferable limitations are imposed thereon, however, the scope of the present disclosure is not limited to the embodiment unless there is a description that the present disclosure is limited thereto in particular in the following description.

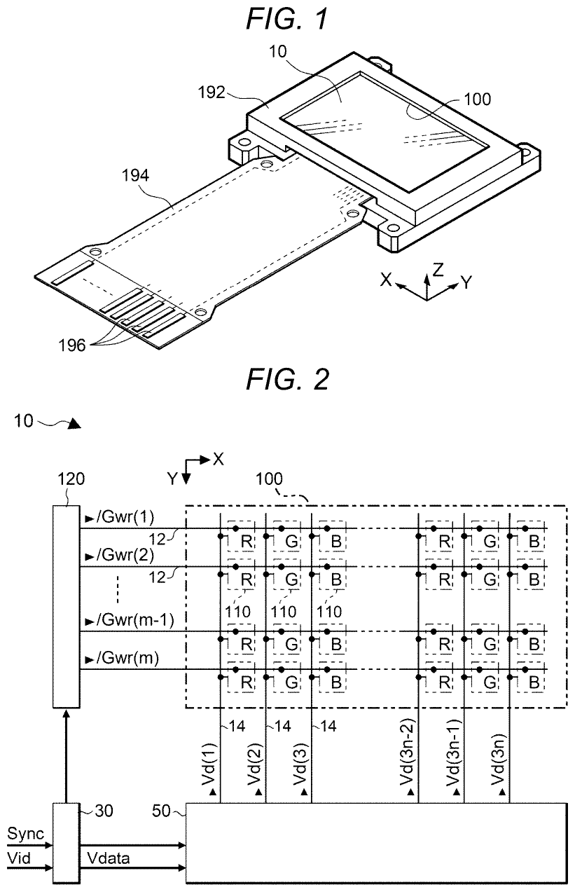

FIG. 1 is a perspective view illustrating an electro-optical device 10 according to a first embodiment, and FIG. 2 is a block diagram illustrating an electric configuration of the electro-optical device 10.

The electro-optical device 10 is, for example, a micro display panel that displays a color image in a head-mounted display or the like. The electro-optical device 10 includes a plurality of pixel portions, drive circuits that drive the pixel portions, and the like. The pixel portions and the drive circuits are integrated on a semiconductor substrate. The semiconductor substrate is typically a silicon substrate, and may be another semiconductor substrate.

The electro-optical device 10 is accommodated in a frame-shaped case 192 that opens in a display region 100. One end of an FPC substrate 194 is coupled to the electro-optical device 10. Note that FPC is an abbreviation for flexible printed circuits. A plurality of terminals 196 for coupling a host device (not illustrated) are provided on the other end of the FPC substrate 194. When the plurality of terminals 196 are coupled to the host device, video data, a synchronization signal, and the like are supplied from the host device to the electro-optical device 10 via the FPC substrate 194.

In the drawings, an X direction is an extending direction of a scanning line in the electro-optical device 10, and indicates a horizontal direction in a display screen. A Y direction is an extending direction of a data line, and indicates a vertical direction in the display screen. A two-dimensional plane defined by the X direction and the Y direction is a substrate surface of the semiconductor substrate. A Z direction is perpendicular to the substrate surface in a semiconductor substrate and is an emission direction of light emitted from a light emitting element. In the present description, a plan view means that the semiconductor substrate is viewed from a direction opposite to the Z direction, and a cross-sectional view means that the semiconductor substrate is viewed by being broken in a direction perpendicular to the substrate surface.

As illustrated in FIG. 2, the electro-optical device 10 is roughly divided into a control circuit 30, a data signal output circuit 50, the display region 100, and a scanning line drive circuit 120.

In the display region 100, m rows of scanning lines 12 are provided along the X direction, and (3n) columns of data lines 14 are provided along the Y direction so as to be electrically insulated from the scanning lines 12. Note that m and n are integers of 2 or more.

In the display region 100, pixel portions 110 are provided corresponding to intersections of the m rows of scanning lines 12 and the (3n) columns of data lines 14. Therefore, the pixel portions 110 are arranged in a matrix of vertical m rows×horizontal (3n) columns. In order to distinguish rows in the matrix arrangement, the rows may be referred to as 1st, 2nd, 3rd, . . . , (m-1)-th, and m-th rows from the top in the drawing. Similarly, in order to distinguish the columns of the matrix, the columns may be referred to as 1st, 2nd, 3rd, . . . , (3n-2)-th, (3n-1)-th, and (3n)-th columns from the left in the drawing.

Note that in order to generalize and describe the scanning lines 12, an integer i of 1 or more and m or less is used. Similarly, in order to generalize and describe the data lines 14, an integer j of 1 or more and (3n) or less is used.

The control circuit 30 controls each unit based on video data Vid and a synchronization signal Sync supplied from an upper host device (not illustrated). Specifically, the control circuit 30 generates various control signals for controlling each unit.

The video data Vid designates a grayscale level of a pixel in an image to be displayed by, for example, 8 bits. The synchronization signal Sync includes a vertical synchronization signal instructing a start of vertical scanning of the video data Vid, a horizontal synchronization signal instructing a start of horizontal scanning, and a dot clock signal indicating a timing of one pixel of the video data.

In the embodiment, pixels of the image to be displayed and the pixel portions 110 in the display region 100 correspond one-to-one.

Luminance characteristics at the grayscale level indicated by the video data Vid supplied from the host device and luminance characteristics of an OLED included in the pixel portion 110 do not necessarily match. Therefore, in order to cause the OLED to emit light at luminance corresponding to the grayscale level indicated by the video data Vid, the control circuit 30 up-converts 8 bits of the video data Vid to, for example, 10 bits and outputs the data as video data Vdata. Therefore, the 10-bit video data Vdata is data corresponding to the grayscale level designated by the video data Vid.

Note that, for the up-conversion, a lookup table is used in which a correspondence relationship between 8 bits of the video data Vid as an input and 10 bits of the video data Vdata as an output is stored in advance.

The scanning line drive circuit 120 is a circuit for driving the pixel portions 110 arranged in m rows and (3n) columns for each row under the control of the control circuit 30. For example, the scanning line drive circuit 120 supplies scanning signals/Gwr(1), /Gwr(2), . . . , /Gwr(m-1), and /Gwr(m) to the scanning lines 12 in the 1st, 2nd, 3rd, . . . (m-1)-th, and m-th rows in order. Generally, the scanning signal supplied to the scanning line 12 in the i-th row is expressed as /Gwr(i).

The data signal output circuit 50 is a circuit that outputs, via the data line 14, under the control of the control circuit 30, a data signal to the pixel portion 110 located in a row selected by the scanning line drive circuit 120. The data signal is a voltage signal obtained by converting the 10-bit video data Vdata into an analog signal. That is, the data signal output circuit 50 converts one row of the video data Vdata corresponding to the pixel portions 110 in columns 1 to (3n) in the selected row into analog data and outputs the analog data to the data lines 14 in the 1st to (3n)-th columns in order.

In the drawing, the data signals output to the data lines 14 in the 1st, 2nd, 3rd, . . . , (3n-2)-th, (3n-1)-th, and (3n)-th columns are expressed, in order, as Vd(1), Vd(2), Vd(3), . . . , Vd(3n-2), Vd(3n-1), and Vd(3n). Generally, a potential of the data line 14 in the j-th column is expressed as Vd(j).

In the pixel portion 110 in the display region 100, as illustrated in FIG. 2, electrically, the R pixel portion 110, the B pixel portion 110, and the G pixel portion 110 are arranged in order along the X direction, and the pixel portions 110 of the same color are arranged along the Y direction. Therefore, when attention is paid to any one column of the data lines 14, the pixel portions 110 of the same color correspond thereto.

Note that one dot expresses a color by additive color mixing of the RBG pixel portions 110 adjacent in the X direction. Therefore, in the first embodiment, a color display of vertical m rows×horizontal n columns can be performed by dots. The pixel portion 110 should be strictly referred to as a sub-pixel portion, but is referred to as a pixel portion for convenience of description.

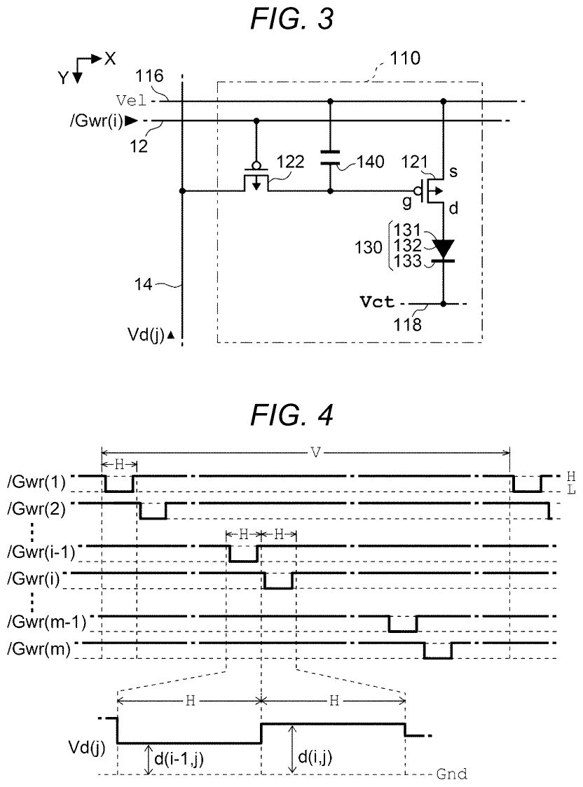

FIG. 3 is a diagram illustrating an electric configuration of the pixel portion 110 in the electro-optical device 10. Electrically speaking, the pixel portions 110 arranged in m rows and (3n) columns are identical to one another. Therefore, the pixel portion 110 will be described by using one pixel portion 110 corresponding to the i-th row and J-th column as a representative.

As illustrated in the drawing, electrically speaking, the pixel portion 110 includes P-channel MOS type transistors 121 and 122, an OLED 130, and a capacitive element 140.

Note that in the description of the pixel portion 110, the phrase “electrically speaking” is used when referring to a plurality of elements forming the pixel portion 110 and a connection relationship between the plurality of elements. Such an expression is used since, mechanically or physically speaking, the pixel portion 110 includes elements that do not contribute to an electrical connection relationship.

The OLED 130 is an example of the light emitting element, and includes a pixel electrode 131, a common electrode 133, and an organic layer 132 including a light emitting layer, the organic layer 132 being sandwiched between the pixel electrode 131 and the common electrode 133. As described above, the pixel electrode 131 functions as an anode of the OLED 130, and the common electrode 133 functions as a cathode of the OLED 130. Note that details of the OLED 130 will be described later, and when a current flows from the anode to the cathode, holes injected from the anode and electrons injected from the cathode are recombined in the light emitting layer to generate excitons, thereby generating light.

Of the generated light, partial light in a wavelength region resonates in an optical resonator including a reflective electrode (omitted in FIG. 3) and the common electrode 133 of a semi-reflective and semi-transmissive layer, and is emitted after being enhanced in wavelength by the resonator, while other light in the wavelength region is emitted without resonating in the optical resonator. In the embodiment, the partial light is blue light, and the other light is yellow light. Therefore, the light emitted from the OLED 130 becomes white by mixing the blue light and the yellow light. Note that the light emitted from the OLED 130 passes through a colored layer of a color corresponding to the pixel portion 110 and is visually recognized by an observer with color light of the colored layer.

For the transistor 121 of the pixel portion 110 in the i-th row and j-th column, a gate node g is coupled to a drain node of the transistor 122, a source node s is coupled to a power supply line 116 of a voltage Vel, and a drain node d is coupled to the pixel electrode 131 which is the anode of the OLED 130.

For the transistor 122, a gate node is coupled to the scanning line 12 in the i-th row, and a source node is coupled to the data line 14 in the j-th column. The common electrode 133 functioning as the cathode of the OLED 130 is coupled to a power supply line 118 of a voltage Vct. Since the electro-optical device 10 is formed on a silicon substrate, a substrate potential of the transistors 121 and 122 is, for example, a potential corresponding to the voltage Vel.

A voltage (Vel-Vct) is a drive voltage of the OLED 130.

Electrically speaking, the pixel portion 110 illustrated in FIG. 3 is common to all the colors of red, green, and blue, and has been generally described without specifying a color. However, structurally speaking, the pixel portion 110 differs for each color. Therefore, when the pixel portions 110 are described by being distinguished by the color, the pixel portions 110 are expressed as pixel portions 110R, 110G, and 110B. Similarly, when the OLEDs 130 and the pixel electrodes 131 are described by being distinguished by the color, the OLEDs 130 are expressed as OLEDs 130R, 130G, and 130B, and the pixel electrodes 131 are expressed as pixel electrodes 131R, 131G, and 131B.

FIG. 4 is a timing chart illustrating an operation of the electro-optical device 10.

In the electro-optical device 10, m rows of the scanning lines 12 are scanned one by one in a period of a frame (V) in order of the 1st, 2nd, 3rd, . . . , and m-th rows. Specifically, as illustrated in the drawing, the scanning signals /Gwr(1), /Gwr(2), . . . , /Gwr(m-1), and /Gwr(m) are sequentially and exclusively set to an L level for each horizontal scanning period (H) by the scanning line drive circuit 120.

Note that in the embodiment, periods in which adjacent scanning signals among the scanning signals /Gwr(1) to /Gwr(m) are at the L level are temporally isolated from each other. Specifically, after the scanning signal /Gwr (i-1) changes from the L level to an H level, the next scanning signal /Gwr(i) is at the L level after a period. The period corresponds to a horizontal blanking period.

In the present description, the period of one frame (V) refers to a period required to display one frame of an image designated by the video data Vid. When a length of the period of one frame (V) is the same as that of a vertical synchronization period, specifically, when a frequency of the vertical synchronization signal included in the synchronization signal Sync is 60 Hz, the length is 16.7 milliseconds corresponding to one cycle of the vertical synchronization signal. The horizontal scanning period (H) is a time interval during which the scanning signals /Gwr(1) to /Gwr(m) are at the L level in order, but for the sake of convenience in the drawing, a start timing of the horizontal scanning period (H) is set to substantially a center of the horizontal blanking period.

When a certain scanning signal among the scanning signals /Gwr(1) to /Gwr(m), for example, the scanning signal /Gwr(i) supplied to the scanning line 12 in the i-th row is at the L level, in the j-th column, the transistor 122 in the pixel portion 110 in the i-th row and j-th column is turned on. Therefore, the gate node g of the transistor 121 in the pixel portion 110 is electrically coupled to the data line 14 in the j-th column.

Note that, in the present description, the “on state” of the transistor means that a source node and a drain node of the transistor are electrically closed to be in a low impedance state. The “off state” of the transistor means that the source node and the drain node are electrically opened to be in a high impedance state.

In the present description, the phrase “electrically coupled” or simply “coupled” means a direct or indirect connection or coupling between two or more elements. The term “electrically not coupled” or simply “not coupled” means that there is no direct or indirect connection or coupling between two or more elements.

In the horizontal scanning period (H) in which the scanning signal /Gwr(i) is at the L level, the data signal output circuit 50 converts grayscale levels of pixels in the i-th row and 1st column to the i-th row and (3n)-th column that are indicated by the video data Vdata into analog potentials Vd(1) to Vd(3n), and outputs, as data signals, the analog potentials Vd(1) to Vd(3n) to the data lines 14 in the 1st to (3n)-th columns. In the j-th column, the data signal output circuit 50 converts a grayscale level d(i, j) of the pixel in the i-th row and j-th column into a potential Vd(j) of an analog signal, and outputs, as a data signal, the potential Vd(j) to the data line 14 in the j-th column.

Note that, in the horizontal scanning period (H) in which the scanning signal /wr(i-1) one row before the scanning signal /wr(i) is at the L level, the data signal output circuit 50 converts a grayscale level d(i-1,j) of a pixel in the (i-1)-th row and j-th column into a potential Vd(j) of an analog signal, and outputs, as the data signal, the potential Vd(j) to the data line 14 in the j-th column.

The data signal of the potential Vd(j) is applied to the gate node g of the transistor 121 in the pixel portion 110 in the i-th row and j-th column via the data line 14 in the j-th column, and the potential Vd(j) is retained by the capacitive element 140. Therefore, the transistor 121 causes a current according to a voltage between the gate node and the source node to flow to the OLED 130.

Even when the scanning signal Gwr(i) is at the H level and the transistor 122 is turned off, the potential Vd(j) can be retained by the capacitive element 140, and thus a current continues to flow through the OLED 130. Therefore, in the pixel portion 110 in the i-th row and j-th column, until the period of one frame (V) elapses, the transistor 122 is turned on again, and the voltage of the data signal is applied again, the OLED 130 continues to emit light at the voltage retained by the capacitive element 140, that is, brightness according to the grayscale level.

Note that although the pixel portion 110 in the i-th row and j-th column has been described here, the OLEDs 130 of the pixel portions 110 in the i-th row and other columns than the j-th column also emit light with the luminance indicated by the video data Vdata.

Even for the OLEDs 130 of the pixel portions 110 in rows other than the i-th row, when the scanning signals /wr(1) to /wr(m) are at the L level in order, light is emitted with the luminance indicated by the video data Vdata.

Therefore, in the electro-optical device 10, in the period of one frame (V), the OLEDs 130 in all the pixel portions 110 from the 1st row and 1st column to m-th row and (3n)-th column emit light with the luminance indicated by the video data Vdata, thereby displaying an image of one frame.

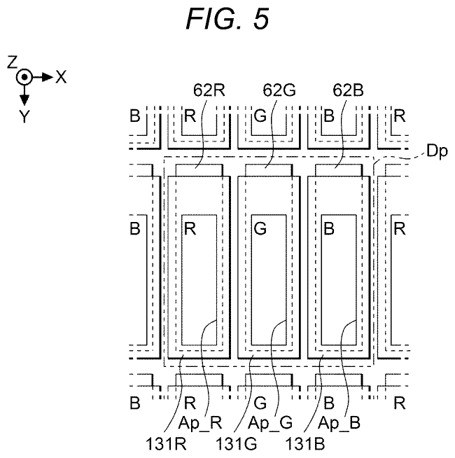

FIG. 5 is a diagram simply illustrating a configuration of the pixel portion 110 in the display region 100 in plan view. In the display region 100, a color of one dot is expressed by additive color mixing of color light emitted from three regions surrounded by a frame Dp in the drawing. Specifically, in the frame Dp, regions R, G, and B are arranged in this order along the X direction. White light emitted from the region R passes through a colored layer (not illustrated in FIG. 5) on a front side of the sheet, and is thereby colored into red light and then emitted. Similarly, pieces of white light emitted from the regions G and B are colored into green and blue light in order by passing through the colored layer and then emitted.

In the pixel portion 110R, a reflective electrode 62R and the pixel electrode 131R are stacked in order. Note that the reflective electrode 62R is electrically coupled to the drain node d of the transistor 121 via a contact hole that opens an insulating layer.

The insulating layer provided between the drain node d and the reflective electrode 62R in the transistor 121 and the contact hole that opens the insulating layer are not illustrated.

The reflective electrode 62R is a light-reflective conductive electrode patterned in a rectangular shape as illustrated in FIG. 5 in correspondence with the pixel portion 110R, and reflects, in the Z direction, light entering from a direction opposite to the Z direction. As the reflective electrode 62R, for example, a conductive layer is used in which an alloy (AlCu) film of aluminum and copper is stacked on a titanium (Ti) film.

The pixel electrode 131R is a conductive electrode obtained by patterning, for example, indium tin oxide (ITO) having transmissivity into a rectangular shape so as to overlap the reflective electrode 62R.

The pixel electrode 131R is formed by patterning an ITO film same as that for the pixel electrodes 131G and 131B corresponding to other colors. When a thickness of the pixel electrodes 131R, 131G, and 131B is 15 nm and a refractive index of the ITO is 1.98, an optical distance, which is a product of the thickness and the refractive index, of the pixel electrodes 131R, 131G, and 131B is 29.7 nm.

The same applies to the pixel portions 110G and 110B. Specifically, in the pixel portion 110G, a reflective electrode 62G and the pixel electrode 131G are stacked in order, and in the pixel portion 110B, a reflective electrode 62B and the pixel electrode 131B are stacked in order.

Opening ends Ap_R, Ap_G, and Ap_B are frame ends of openings in the insulating layer that covers the pixel electrodes 131R, 131G, and 131B. In other words, the pixel electrodes 131R, 131G, and 131B are exposed in order through the openings defined by the opening ends Ap_R, Ap_G, and Ap_B in the insulating layer.

In regions where the pixel electrodes 131R, 131G, and 131B are exposed, organic layers and the like described below are stacked. Note that a stack of the organic layers and the like is common to the pixel portions 110R, 110G, and 110B. Therefore, in the following description, reference numerals from the pixel electrode to the common electrode are omitted.

In the electro-optical device 10 according to the embodiment, a tandem element in which three light emitting units are coupled in series is adopted in order to obtain high luminance. A simple tandem element requires a high drive voltage as described above. Therefore, in the embodiment, one of the three light emitting units forming the tandem element, which is closer to the reflective electrode, is of a type using up-conversion from an exciplex.

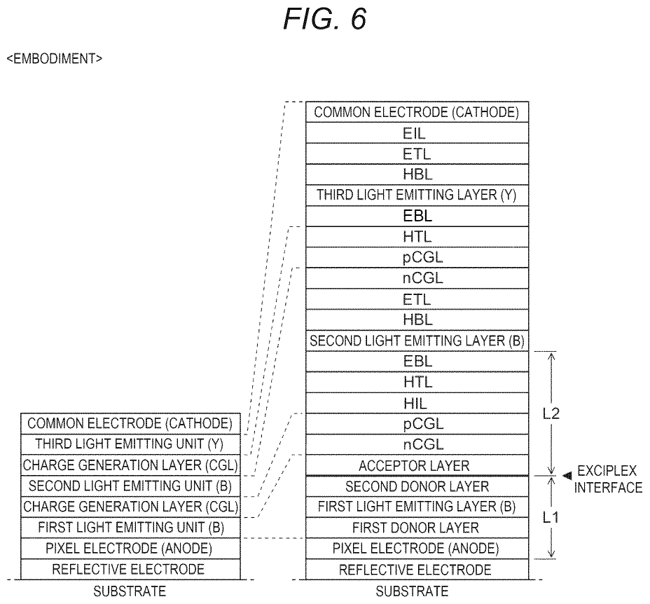

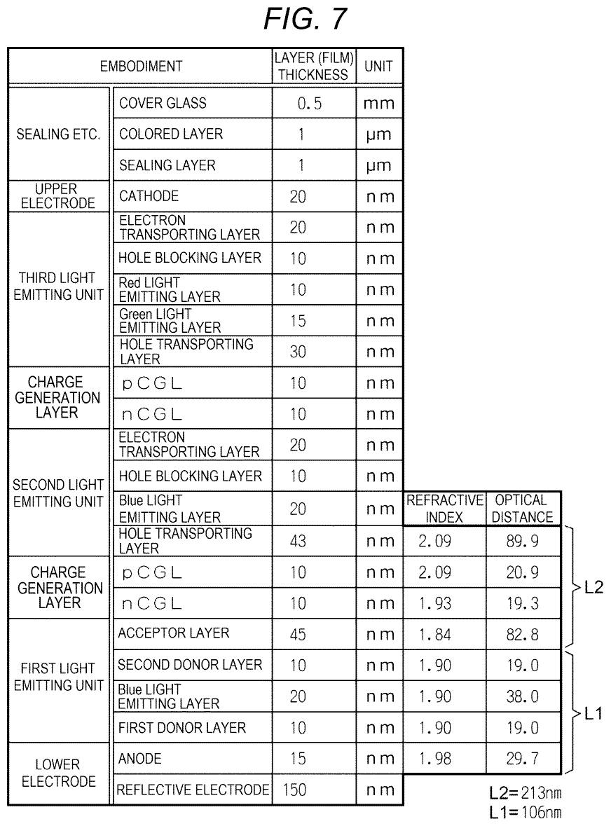

FIG. 6 is a diagram illustrating a layer structure of electrodes, organic layers, and the like stacked in an exposed region of the pixel electrode in the pixel portion. Note that, in the drawing, the left column illustrates an outline of the layer structure, and the right column illustrates details of the layer structure. FIG. 7 is a diagram illustrating an example of thicknesses of the organic layers, the electrode layers, and the like.

As illustrated in the left column in FIG. 6, a first light emitting unit, a charge generation layer, a second light emitting unit, a charge generation layer, a third light emitting unit, and a common electrode are stacked in order in the exposed region of the pixel electrode in the pixel portion.

Note that although not illustrated in the drawing, a sealing layer, a colored layer, and a cover glass are stacked in order on the common electrode.

As illustrated in the right column in FIG. 6, the first light emitting unit has a structure in which a first donor layer, a first light emitting layer, a second donor layer, and an acceptor layer are stacked in order on the pixel electrode.

The first donor layer is made of a material having a lowest unoccupied molecular orbital (LUMO) in an electron transporting layer of about 3.0 eV and a highest occupied molecular orbital (HOMO) of about 6.0 eV, for example, an anthracene derivative.

A thickness of the first donor layer is, for example, 10 nm. When a refractive index of the first donor layer is 1.90, an optical distance of the first donor layer is 19.0 nm.

The first light emitting layer has a host formed of a material same as that of the first donor layer, and is doped with a dopant that emits blue light. In other words, the first light emitting layer is a layer in which a part of a donor layer is doped with a blue light emitting dopant.

A thickness of the first light emitting layer is, for example, 20 nm. When a refractive index of the first light emitting layer is 1.90, an optical distance of the first light emitting layer is 38.0 nm. A wavelength region of the blue light is 400 nm or more and less than 500 nm.

The second donor layer is made of a material same as that of the first donor layer. A thickness of the second donor layer is, for example, 10 nm. When the refractive index of the second donor layer is the same as the refractive index of the first donor layer, an optical distance of the second donor layer is 19.0 nm.

The acceptor layer is made of a material having a LUMO of about 3.8 eV, for example, a naphthalenediimide (NTCDI) derivative. A thickness of the acceptor layer is, for example, 45 nm. When a refractive index of the acceptor layer is 1.84, an optical distance of the acceptor layer is 82.8 nm.

The charge generation layer (CGL) is a pn junction between an n-type charge generation layer (nCGL) and a hole generation layer (pCGL). The nCGL on an n-side of the pn junction generates electrons and injects the electrons into a layer adjacent to an anode side, and the pCGL on a p-side of the pn junction generates holes and injects the generated holes into a layer adjacent to a cathode side.

That is, of the light emitting units in the tandem element, the nCGL of the charge generation layer supplies electrons to the first light emitting unit on the anode side, and the pCGL supplies holes to the second light emitting unit on the cathode side.

A thickness of the nCGL is, for example, 10 nm. When a refractive index of the nCGL is 1.93, an optical distance of the nCGL is 19.3 nm. A thickness of the pCGL is, for example, 10 nm. When a refractive index of the pCGL is 2.09, an optical distance of the pCGL is 20.9 nm.

The second light emitting unit has a structure in which a hole injection layer (HIL), a hole transporting layer (HTL), an electron blocking layer (EBL), a second light emitting layer, a hole blocking layer (HBL), and an electron transporting layer (ETL) are stacked in order.

The HIL is a layer that injects holes into the second light emitting layer from the anode side.

The HTL is a layer that reduces a difference between ionization energy of the second light emitting layer and a work function of the anode. A thickness of the HTL is, for example, 43 nm. In the second light emitting unit, when a refractive index of the HTL is 2.09, an optical distance of the HTL is 89.9 nm.

The EBL is a layer that prevents electrons from overflowing to a layer side of the anode.

Similar to the first light emitting layer, the second light emitting layer has a single-layer structure of a blue light emitting layer that emits blue light in a wavelength region of 400 nm or more and less than 500 nm. Therefore, in the embodiment, a wavelength region of light emitted from the first light emitting layer and a wavelength region of light emitted from the second light emitting layer overlap each other.

Note that in the embodiment, the wavelength regions of light emitted from the first light emitting layer and the second light emitting layer are the same, but the wavelength regions may partially overlap.

A thickness of the second light emitting layer is, for example, 20 nm.

The HBL is a layer that prevents holes from overflowing to a layer side of the cathode. A thickness of the HBL is, for example, 10 nm.

The ETL is a layer that reduces a difference between an electron affinity of the second light emitting layer and a work function of the cathode. A thickness of the ETL is, for example, 20 nm.

A charge generation layer is provided between the second light emitting unit and the third light emitting unit, similar to that between the first light emitting unit and the second light emitting unit. Specifically, the nCGL and the pCGL are provided in order from the second light emitting unit, and thicknesses of the nCGL and the pCGL are also 10 nm.

Similar to the second light emitting unit, the third light emitting unit has a structure in which the HTL, the EBL, the third light emitting layer, the HBL, the ETL, and the EIL are stacked in order from a charge generation layer.

However, in the third light emitting unit, unlike the first light emitting layer and the second light emitting layer, the third light emitting layer has a structure in which a green light emitting layer that emits green light and a red light emitting layer that emits red light are stacked in order. A wavelength region of the green light is 500 nm or more and less than 580 nm, and a wavelength region of the red light is 580 nm or more and less than 700 nm. Therefore, the third light emitting layer emits yellow light in a wavelength region of 500 nm or more and less than 700 nm by mixing the green light and the red light.

Therefore, in the embodiment, the wavelength region of the blue light from the first light emitting layer and the second light emitting layer and the wavelength region of the yellow light from the third light emitting layer do not overlap each other, and the white light is emitted by mixing the blue light and the yellow light.

The EIL is a layer that injects electrons from the cathode, and a material such as an alkali metal or an amorphous oxide having transparency is used.

Note that in the third light emitting unit, thicknesses of the HTL, the green light emitting layer, the red light emitting layer, the HBL, and the ETL are 30 nm, 15 nm, 10 nm, 10 nm, and 20 nm, respectively.

The common electrode of the semi-reflective and semi-transmissive layer serving as the cathode is common to all the pixel portions, and is coupled to the power supply line 118 of the voltage Vct as described above. As the common electrode, for example, an alloy of magnesium and silver is used. A thickness of the common electrode is, for example, 20 nm.

Although omitted in FIG. 6, a sealing layer, a colored layer, and a cover glass are provided so as to cover the common electrode. The sealing layer is a layer that has transmissivity and insulating properties and protects the common electrode and a layer below the common electrode from moisture. As illustrated in FIG. 7, a thickness of the sealing layer is, for example, 1 μm.

The colored layer is a color filter that transmits color light corresponding to a color of the pixel portion. Specifically, the colored layer corresponding to the pixel portion 110R transmits red light, the colored layer corresponding to the pixel portion 110G transmits green light, and the colored layer corresponding to the pixel portion 110B transmits blue light. A thickness of the colored layer is, for example, 1 μm.

The cover glass is a protective material that has transmissivity and protects a surface. A thickness of the cover glass is, for example, 1 mm.

In the embodiment, in the first light emitting unit, a contact surface between the donor layer and the acceptor layer is an exciplex interface, and energy is up-converted by triplet triplet annihilation (TTA). By this up-conversion, blue light can be generated with a drive voltage that is low compared to wavelength energy.

In the embodiment, both the first light emitting unit and the second light emitting unit emit blue light. Here, assuming that the wavelength of the blue light is 460 nm, the following optical distance may be used in order to increase extraction efficiency of the blue light in the optical resonator.

In FIGS. 6 and 7, a first optical distance L1 is expressed as a cumulative value of products obtained by multiplying a distance from an interface between the reflective electrode and the pixel electrode to an interface between the second donor layer and the acceptor layer by the refractive index of each layer.

In FIGS. 6 and 7, a second optical distance L2 is expressed as a cumulative value of products obtained by multiplying a distance from an interface between the donor layer and the acceptor layer to the EBL and the second light emitting layer in the second light emitting unit by the refractive index of each layer.

In order to increase the extraction efficiency of the blue light having a wavelength of 460 nm, the first optical distance L1 may be set to 106 nm and the second optical distance L2 may be set to 213 nm. Specifically, the thickness of each layer is adjusted as illustrated in FIG. 7.

In order to describe the superiority of the electro-optical device 10 according to the embodiment, an electro-optical device according to a comparative example will be described.

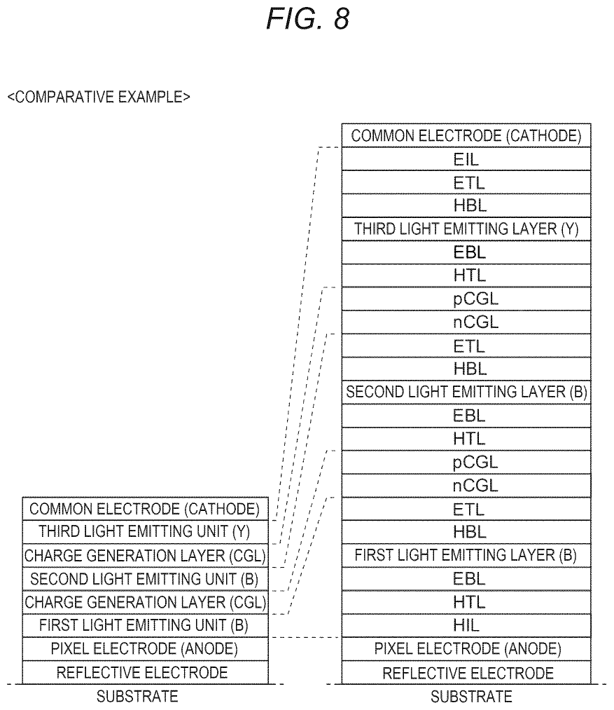

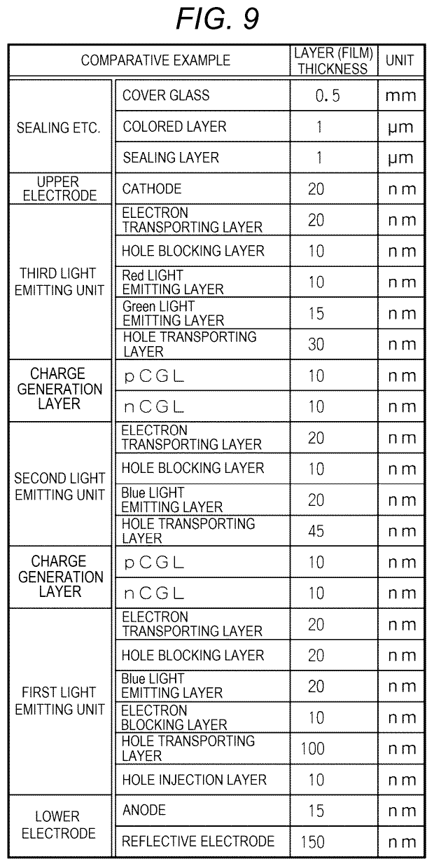

FIG. 8 is a diagram illustrating a layer structure of electrodes, organic layers, and the like stacked in an exposed region of a pixel electrode in a pixel portion of an electro-optical device according to a comparative example. Note that, in the drawing, the left column illustrates an outline of the layer structure, and the right column illustrates details of the layer structure. FIG. 9 is a diagram illustrating an example of thicknesses of the organic layers, the electrode layers, and the like.

In the comparative example, the first light emitting unit has a configuration that does not use an exciplex interface, specifically, the first light emitting unit has a configuration same as that of the second light emitting unit and the third light emitting unit except that the first light emitting layer has a single-layer structure of a blue light emitting layer. That is, in the comparative example, a tandem element is used in which three light emitting units having substantially the same configuration are coupled in series.

Among advantages of the electro-optical device 10 according to the embodiment, the fact that a low drive voltage is sufficient will be described.

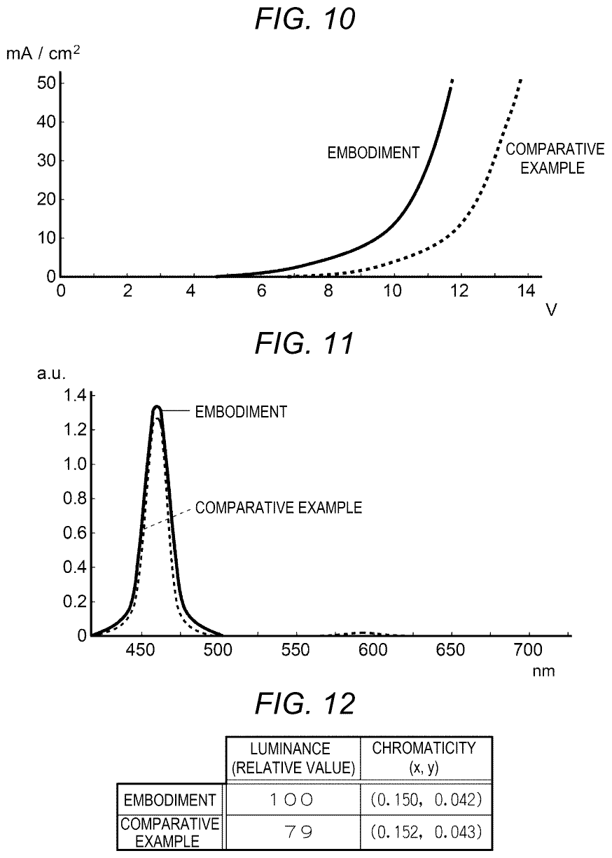

FIG. 10 is a diagram illustrating drive voltage-current density characteristics in the embodiment and the comparative example.

In the comparative example, a tandem element is used in which three light emitting units are simply coupled in series, and thus the drive voltage is high. On the other hand, in the embodiment, in the first light emitting unit, energy is up-converted using the exciplex interface between the donor layer and the acceptor layer to generate blue light, and thus the drive voltage can be made lower than the wavelength energy.

For example, when the electro-optical device 10 has a high-definition pixel portion exceeding, for example, 3000 dpi, a voltage that can be applied to the light emitting element in the semiconductor substrate of the electro-optical device 10 is about 10 V to 12 V at the maximum. In the comparative example, the voltage exceeds the above range in order to obtain necessary luminance, whereas in the embodiment, the voltage within the above range can be kept.

Next, among the advantages of the electro-optical device 10 according to the embodiment, a point that a distance from the first light emitting layer to the reflective electrode can be shortened will be described.

In the comparative example, in order to efficiently extract blue light having a wavelength of 460 nm, it is necessary to adjust the first optical distance L1 to the same value as in the embodiment.

However, in the comparative example, in order to provide the first light emitting layer of the blue light emitting layer with the function of efficiently injecting holes from the anode side and blocking electrons, it is necessary to sandwich the first light emitting layer with a plurality of organic layers. These organic layers cannot exhibit expected functions at a thickness of about several nm. Therefore, as a result, in the comparative example, it is difficult to efficiently extract a color having a wavelength of 460 nm at the same optical distance as in the embodiment. In the comparative example, it is necessary to use the organic layers sandwiching the first light emitting layer with a thickness as illustrated in FIG. 9 so as to increase a resonance order of optical resonance as compared with the embodiment. A difference in resonance order affects a half-value width of the peak waveform due to resonance.

FIG. 11 is a diagram illustrating a comparison of an emission spectrum observed through a blue colored layer having a thickness of 1 μm between the embodiment and the comparative example. FIG. 12 is a diagram illustrating a comparison of luminance and chromaticity observed through the colored layer between the embodiment and the comparative example.

As illustrated in FIG. 11, a half-value width at a peak at the wavelength of 460 nm is wider in the embodiment than that in the comparative example having a large resonance order. Therefore, in the embodiment, as illustrated in FIG. 12, relatively high luminance can be obtained as compared with the comparative example.

Note that, in FIG. 12, the luminance in the embodiment is normalized to 100, and the luminance in the comparative example is shown as a relative value. The chromaticity is represented by coordinate values of x and y in the chromaticity diagram. There is no significant difference in coordinate values of x and y between the embodiment and the comparative example.

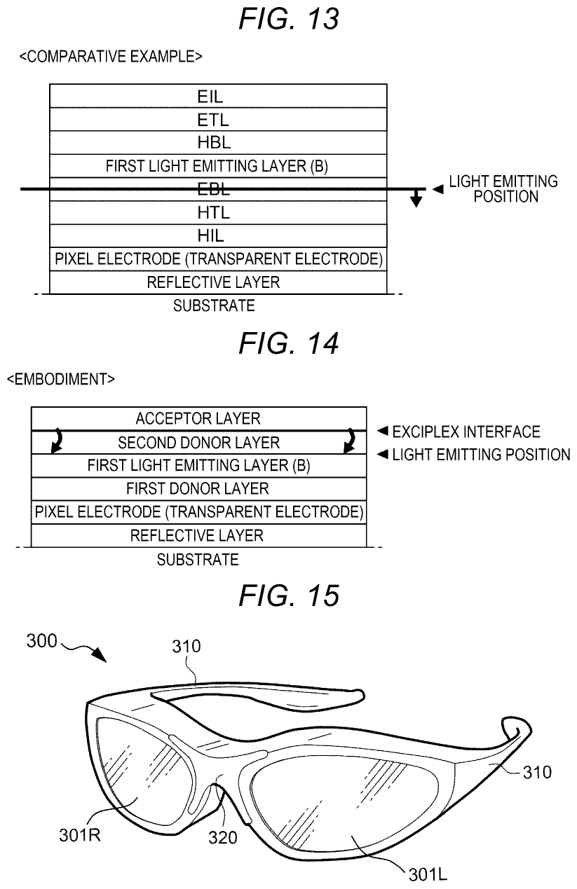

In the comparative example, a light emitting position in the light emitting layer changes depending on a carrier balance, which is a balance between holes and electrons. Specifically, when the hole transporting layer deteriorates due to driving for a long time, that is, when hole transportability decreases, the light emitting position in the light emitting layer moves toward the pixel electrode, which is the anode (opposite to the Z direction), as illustrated in FIG. 13. When the light emitting position moves from an optimum position at the time of design, a distance from the light emitting position to the reflective layer changes, and the light extraction efficiency in the optical resonator decreases.

On the other hand, in the embodiment, the holes and the electrons, which are carriers, are recombined at the exciplex interface. Therefore, even when the carrier balance changes, a carrier recombination position does not change. Since the first light emitting layer emits light by energy transfer from the exciplex interface, as illustrated in FIG. 14, the light emitting position is always close to the acceptor layer in the first light emitting layer.

Therefore, in the embodiment, even when the carrier balance changes, the light emitting position is less likely to change, and thus the distance from the light emitting position to the reflective layer does not change, and the problem of the light extraction efficiency in the optical resonator decreasing does not occur.

Next, an electronic instrument to which the electro-optical device 10 according to the embodiment and the like is applied will be described. The electro-optical device 10 is suitable for applications in which pixels are small and high-definition display is performed. Therefore, a head-mounted display will be described as an example of the electronic instrument.

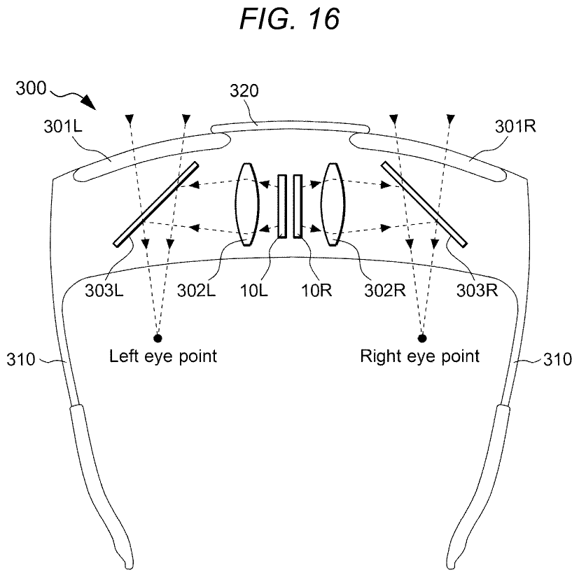

FIG. 15 is a diagram illustrating an appearance of a head-mounted display, and FIG. 16 is a diagram illustrating an optical configuration of the head-mounted display.

First, as illustrated in FIG. 15, a head-mounted display 300 includes temples 310, a bridge 320, and lenses 301L and 301R as in general glasses in appearance. As illustrated in FIG. 16, the head-mounted display 300 includes an electro-optical device 10L for a left eye and an electro-optical device 10R for a right eye that are provided near the bridge 320 and on a rear side of the lenses 301L and 301R (lower side in the drawing).

An image display surface of the electro-optical device 10L is disposed on the left in FIG. 16. Accordingly, a display image by the electro-optical device 10L is emitted in a direction of 9 o'clock in the drawing via an optical lens 302L. A half mirror 303L reflects a display image by the electro-optical device 10L in a direction of 6 o'clock, while transmitting light entering from a direction of 12 o'clock. An image display surface of the electro-optical device 10R is disposed on the right opposite to the electro-optical device 10L. Accordingly, a display image by the electro-optical device 10R is emitted in a direction of 3 o'clock in the drawing via an optical lens 302R. A half mirror 303R reflects a display image by the electro-optical device 10R in a direction of 6 o'clock, while transmitting light entering from a direction of 12 o'clock.

In this configuration, a wearer of the head-mounted display 300 can observe display images by the electro-optical devices 10L and 10R in a see-through state superimposed over the external scenery.

In the head-mounted display 300, when the electro-optical device 10L displays an image for the left eye and the electro-optical device 10R displays an image for the right eye among binocular images with parallax, the wearer can perceive the displayed image as if the displayed image had a depth or a stereoscopic effect.

The electronic instrument including the electro-optical device 10 can be used not only as the head-mounted display 300, but also as an electronic viewfinder in a video camera and an interchangeable-lens digital camera, a portable information terminal, a display unit in wristwatches, and a light valve in a projection projector.

From the above description, for example, preferred aspects of the present disclosure are understood as follows.

An electro-optical device according to Aspect 1 of the present disclosure includes: a light emitting element including a first electrode having reflectivity, a first light emitting layer configured to emit light in a first wavelength region including a first wavelength, a donor layer, an acceptor layer in contact with the donor layer, a second light emitting layer configured to emit light in a second wavelength region including a second wavelength, and a second electrode having reflectivity and transparency, stacked in order. The first wavelength region and the second wavelength region overlap partially or entirely.

In the electro-optical device according to Aspect 1, the tandem element is provided in which the first light emitting layer and the second light emitting layer are coupled in series, and thus high luminance can be secured. The first light emitting layer of the tandem element can be driven at a low voltage by an exciplex of the donor layer and the acceptor layer, and thus the tandem element can be driven at a low voltage.

Note that the reflective electrode and the pixel electrode are an example of the “first electrode”, and the common electrode is an example of the “second electrode”.

In the electro-optical device according to specific Aspect 2 of Aspect 1, the light emitting element further includes a third light emitting layer provided between the second light emitting layer and the second electrode and configured to emit light in a third wavelength region including a third wavelength different from the first wavelength.

In the electro-optical device according to Aspect 2, the third light emitting layer emits light having a third wavelength including a wavelength different from the first wavelength.

In the electro-optical device according to specific Aspect 3 of Aspect 2, the third wavelength region does not overlap the first wavelength region, and the third wavelength is longer than the first wavelength.

In the electro-optical device according to Aspect 3, light emitted from the light emitting element can be easily made white.

An electronic instrument according to Aspect 4 includes the electro-optical device according to any one of Aspects 1 to 3.

What is claimed is:

1. An electro-optical device, comprising:
a light emitting element including
a first electrode having reflectivity,
a first light emitting layer configured to emit light in a first wavelength region including a first wavelength,
a donor layer,
an acceptor layer in contact with the donor layer,
a second light emitting layer configured to emit light in a second wavelength region including a second wavelength, and
a second electrode having reflectivity and transparency, stacked in order, wherein
the first wavelength region and the second wavelength region overlap partially or entirely.

2. The electro-optical device according to claim 1, wherein
the light emitting element further includes a third light emitting layer provided between the second light emitting layer and the second electrode and configured to emit light in a third wavelength region including a third wavelength different from the first wavelength.

3. The electro-optical device according to claim 2, wherein
the third wavelength region does not overlap the first wavelength region, and
the third wavelength is longer than the first wavelength.

4. An electronic instrument, comprising:
the electro-optical device according to claim 1.
